(19) United States
(12) Patent Application Publication
(10) Pub. No.: US 2025/0132243 A1
(43) Pub. Date: Apr. 24, 2025

(54) SEMICONDUCTOR PACKAGE

(71) Applicant: Samsung Electronics Co., Ltd., Suwon-si (KR)

(72) Inventors: Sungmin Baek, Suwon-si (KR); Seungwan Kim, Suwon-si (KR); Joohyung Lee, Suwon-si (KR); Hyunwook Choi, Suwon-si (KR)

(21) Appl. No.: 18/659,703

(22) Filed: May 9, 2024

(30) Foreign Application Priority Data
Oct. 20, 2023 (KR) 10-2023-0141247

(51) Int. Cl. H01L 23/498; H01L 23/00; H01L 23/31

(52) U.S. Cl. CPC H01L 23/49894; H01L 23/3128; H01L 23/49811; H01L 24/25; H01L 2224/2518

(57) ABSTRACT

A semiconductor package includes a lower redistribution structure including a lower redistribution layer; an interconnection structure disposed on the lower redistribution structure, having internal side surfaces defining a through-portion, external side surfaces, and corner surfaces defining recess portions between adjacent external side surfaces, and including a fiber layer having first fiber ends adjacent to at least a portion of the corner surfaces, an insulating resin layer in which the fiber layer is embedded, and an interconnection layer disposed on at least one surface of the insulating resin layer and electrically connected to the lower redistribution layer; a semiconductor chip disposed in the through-portion of the interconnection structure and including connection pads electrically connected to the lower redistribution layer; an encapsulant disposed in the through-portion and the recess portions of the interconnection structure; an upper redistribution structure disposed on the encapsulant and including an upper redistribution layer electrically connected to the lower redistribution layer; and connection bumps disposed below the lower redistribution structure and electrically connected to the lower redistribution layer.

### CROSS-REFERENCE TO RELATED APPLICATION(S)

This application claims benefit of priority to Korean Patent Application No. 10-2023-0141247 filed on Oct. 20, 2023, in the Korean Intellectual Property Office, the disclosure of which is incorporated herein by reference in its entirety.

### BACKGROUND

Example embodiments relate to a semiconductor package.

A semiconductor package includes dissimilar components such as a semiconductor chip, a redistribution structure, and an encapsulant, each of which may include dissimilar materials. Warpage of the semiconductor package may occur due to a difference in thermal expansion coefficients between dissimilar materials. To control warpage of a semiconductor package, development of a semiconductor package using a structure reinforced with a fiber layer has been conducted.

### SUMMARY

Embodiments are directed to a method for producing a semiconductor package having improved yield and a semiconductor package.

According to an example embodiment, a semiconductor package includes a lower redistribution structure including a lower redistribution layer; an interconnection structure disposed on the lower redistribution structure, having internal side surfaces defining a through-portion, external side surfaces opposite to the internal side surfaces, and corner surfaces defining recess portions between adjacent external side surfaces, and including a fiber layer having first fiber ends adjacent to at least a portion of the corner surfaces, an insulating resin impregnated in the fiber layer, and an interconnection layer disposed on at least one surface of the insulating resin layer and electrically connected to the lower redistribution layer; a semiconductor chip disposed in the through-portion of the interconnection structure and including connection pads electrically connected to the lower redistribution layer; an encapsulant disposed in the through-portion and the recess portions of the interconnection structure; an upper redistribution structure disposed on the encapsulant and including an upper redistribution layer electrically connected to the lower redistribution layer; and connection bumps disposed below the lower redistribution structure and electrically connected to the lower redistribution layer.

According to an example embodiment in the example embodiment, a semiconductor package includes a lower redistribution structure including a lower redistribution layer; a semiconductor chip disposed on the lower redistribution structure and including connection pads electrically connected to the lower redistribution layer; an interconnection structure surrounding the semiconductor chip, having external side surfaces and corner surfaces between adjacent external side surfaces, and including an insulating resin layer with an insulating resin impregnated in a fiber layer, interconnection layers disposed on two surfaces of the insulating resin layer, and an interconnection via penetrating the insulating resin layer and electrically connecting the interconnection layers to each other; an encapsulant covering at least a portion of each of the semiconductor chip and the interconnection structure; and an upper redistribution structure including an insulating layer disposed on the encapsulant, an upper redistribution layer on the insulating layer, and an upper redistribution via penetrating the insulating layer and electrically connecting the upper redistribution layer to the interconnection layers, wherein the fiber layer has fiber ends with at least a portion cut-out by the corner surfaces.

According to an example embodiment in the example embodiment, a semiconductor package includes a lower redistribution structure including a lower redistribution layer; a semiconductor chip disposed on the lower redistribution structure and including connection pads electrically connected to the lower redistribution layer; a frame structure disposed on the lower redistribution structure, and having internal side surfaces surrounding a side surface of the semiconductor chip, external side surfaces opposite to the internal side surfaces, and corner surfaces connecting adjacent external side surfaces; and an encapsulant covering the side surface of the semiconductor chip and the corner surfaces of the frame structure.

### BRIEF DESCRIPTION OF DRAWINGS

The above and other aspects, features, and advantages in the example embodiment will be more clearly understood from the following detailed description, taken in combination with the accompanying drawings, in which:

FIGS. 1A and 1B are cross-sectional diagrams illustrating a semiconductor package according to an example embodiment of the present disclosure;

FIG. 1C is a plan diagram taken along line I-I′ in FIGS. 1A and 1B;

FIGS. 2A to 2D are diagrams illustrating a frame structure of a modified example embodiment;

FIG. 3 is a cross-sectional diagram illustrating a semiconductor package according to an example embodiment of the present disclosure;

FIGS. 4A to 9 are diagrams illustrating a process of manufacturing a package structure according to an example embodiment of the present disclosure;

FIGS. 10A to 10C are diagrams illustrating a process of sawing a package structure according to an example embodiment of the present disclosure; and

FIGS. 11A to 11C are diagrams illustrating a sawing process of a comparative example.

### DETAILED DESCRIPTION

Hereinafter, example embodiments will be described in detail with reference to the accompanying drawings. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

Unless otherwise described, spatially relative terms such as “upper,” “upper portion,” “upper surface,” “lower,” “lower portion,” “lower surface,” and “side surface” are used for ease of description to describe positional relationships and are based on the orientation shown in the drawings. It will be understood that spatially relative terms are intended to encompass orientations other than those shown in the drawings and may vary depending on a direction in which an element or component is actually arranged.

In addition, ordinal numbers such as “first,” “second,” “third,” and the like may be used as labels for specific elements, operations, directions, and the like, to distinguish various elements, steps, directions, and the like from one another, and unless otherwise indicated, are not representative of a specific order. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

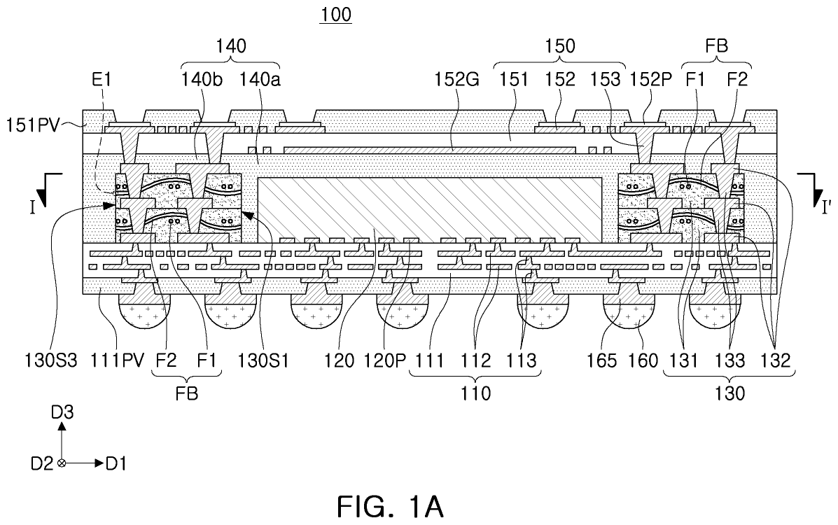

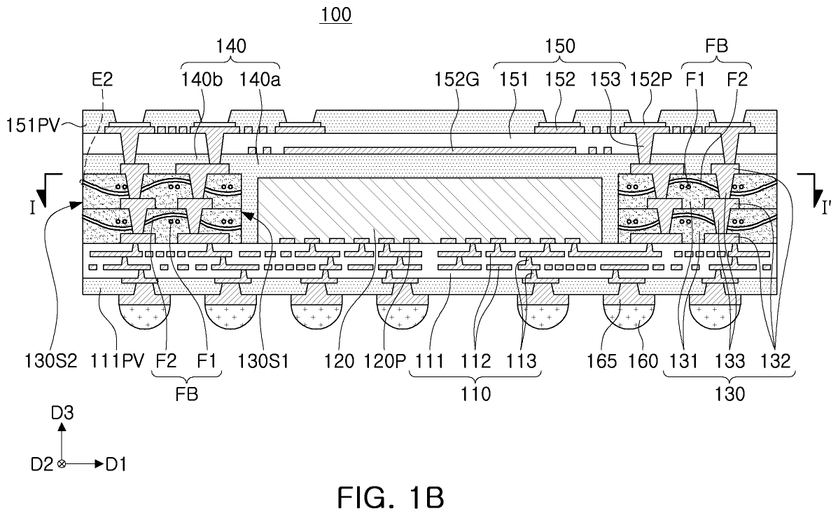

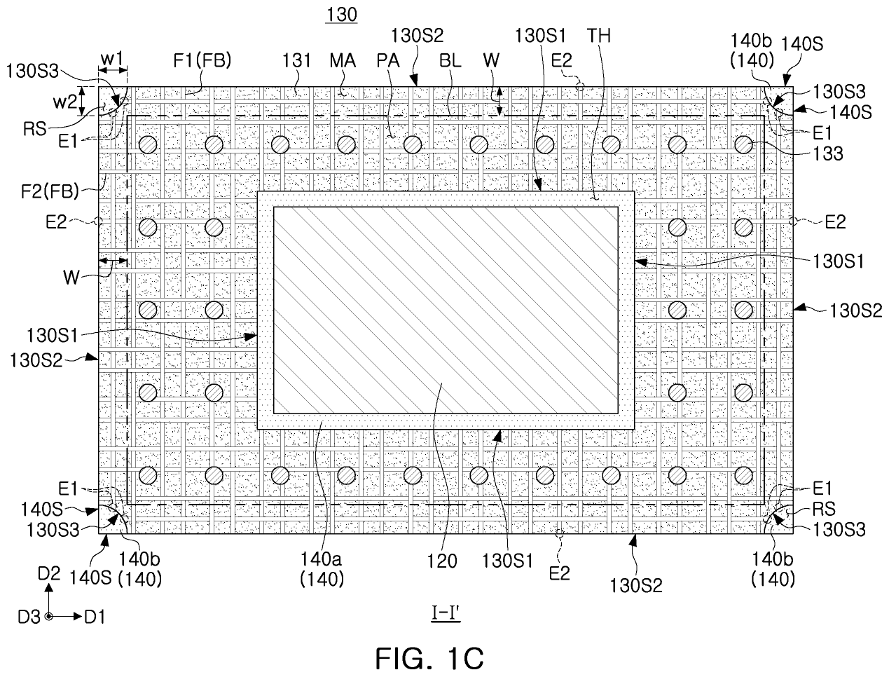

FIGS. 1A and 1B are cross-sectional diagrams illustrating a semiconductor package according to an example embodiment. FIG. 1C is a plan diagram taken along line I-I′ in FIGS. 1A and 1B.

Referring to FIGS. 1A, 1B, and 1C, a semiconductor package 100 in an example embodiment may include a lower redistribution structure 110, a semiconductor chip 120, a frame structure 130, and an encapsulant 140. In example embodiments, the semiconductor package 100 may further include an upper redistribution structure 150.

The lower redistribution structure 110 may be configured as a support substrate on which the semiconductor chip 120 is mounted, and may include a lower insulating layer 111, a lower redistribution layer 112, and a lower redistribution via 113. The lower redistribution structure may include layers other than the lower insulating layer 111, the lower redistribution layer 112, and the lower redistribution via 113 and/or a layer described in the example in the diagram may be omitted.

The lower insulating layer 111 may be formed of and/or include insulating resin. The insulating resin may be a thermosetting resin such as epoxy resin, a thermoplastic resin such as polyimide, or a resin including inorganic filler or/and glass fiber, glass cloth, glass fabric, such as prepreg, Ajinomoto Build-up Film (ABF), FR-4, and BT. For example, the lower insulating layer 111 may be formed of and/or include a photosensitive resin such as photoimageable dielectric (PID). The lower insulating layer 111 may include a plurality of lower insulating layers 111 stacked in the vertical direction D3. Depending on processes, boundaries between the plurality of lower insulating layers 111 may be indistinct. For example, the plurality of lower insulating layers 111 may be indistinguishable from a single layer after manufacturing.

As used herein, the singular forms “a”, “an” and “the” are intended to include the plural forms as well, unless the context clearly indicates otherwise. For example, when describing components that are formed of multiple sub-components, “the component” is intended to encompass a combination of a plurality of sub-component that constitute “the component.” Additionally, in examples in which multiple instances of “a component” are present, unless otherwise indicated, “the component” is intended to describe each of the components. When referring to relationships involving a plurality of items, unless otherwise specified, the relationship is intended to include one-to-one, many-to-one, one-to-many, and many-to-many relationships of items in the plurality.

The lower redistribution layer 112 may redistribute the connection pads 120P of the semiconductor chip 120. The lower redistribution layer 112 may be formed of and/or include, for example, a metal material including copper (Cu), aluminum (Al), silver (Ag), tin (Sn), gold (Au), nickel (Ni), lead (Pb), titanium (Ti), or alloys thereof. The lower redistribution layer 112 may include a ground pattern, a power pattern, and a signal pattern. The signal pattern may provide a path through which various signals, such as data signals, are transmitted/received. The signal pattern may not provide a power path or a ground path. The lower redistribution layer 112 may include a plurality of lower redistribution layers 112. At least some of the lower redistribution layers 112 may be electrically connected to another of the lower redistribution layers 112 through the lower redistribution via 113.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, elements described as being “electrically connected” are configured such that an electrical signal can be passed from one element to the other. Therefore, a passive electrically conductive element (e.g., a wire, pad, internal electrical line, etc.) physically connected to a passive electrically insulative element (e.g., a prepreg layer of a printed circuit board, an electrically insulative adhesive connecting two devices, an electrically insulative underfill or mold layer, etc.) is not electrically connected to that element. Moreover, elements that are “directly electrically connected,” to each other are electrically connected through one or more passive elements, such as, for example, wires, pads, internal electrical lines, through vias, etc. Directly electrically connected elements may be directly physically connected and directly electrically connected.

The lower redistribution via 113 may be electrically connected to the lower redistribution layer 112 and may include a signal via, a ground via, and a power via. The lower redistribution via 113 may be formed of and/or include, for example, a metal material including copper (Cu), aluminum (Al), silver (Ag), tin (Sn), gold (Au), nickel (Ni), lead (Pb), titanium (Ti), or alloys thereof. The lower redistribution via 113 may be a filled via in which metal material is filled in the via-hole, or a conformal via in which a metal material is formed along an internal wall of the via-hole. The lower redistribution via 113 may be integrated with the lower redistribution layer 112, but the invention is not limited thereto.

Connection bumps 160 may be disposed below the lower redistribution structure 110. The connection bumps 160 may connect the semiconductor package 100 to an external device such as a module substrate and a main board. The connection bumps 160 may be formed of and/or include a low melting point metal, for example, tin (Sn) or an alloy including tin (Sn) (for example, Sn—Ag—Cu).

In example embodiments, the semiconductor package 100 may further include an underbump layer 165 and/or a lower protective layer 111PV. The underbump layer 165 may be disposed between the lowermost lower redistribution layer 112 and the connection bumps 160. The underbump layer 165 may have a thickness greater than that of the lower redistribution layer 112. The underbump layer 165 may be formed of and/or include, for example, a metal material including copper (Cu), aluminum (Al), silver (Ag), tin (Sn), gold (Au), nickel (Ni), lead (Pb), titanium (Ti), or alloys thereof. The lower protective layer 111PV may cover the lowermost lower redistribution layer 112. The lower protective layer 111PV may be formed of and/or include insulating resin such as ABF. The underbump layer 165 may penetrate through the lower protective layer 111PV and may be connected to the lowermost lower redistribution layer 112.

The semiconductor chip 120 may be disposed on the lower redistribution structure 110 and may include a connection pad 120P electrically connected to the lower redistribution layer 112. The semiconductor chip 120 may be disposed in a through-portion TH of the frame structure 130. The semiconductor chip 120 may be a bare integrated circuit (IC) in which no separate bump or no interconnection layer is formed, but the invention is not limited thereto, and the semiconductor chip 120 may be a packaged-type integrated circuit. Accordingly, the connection pad 120P may be understood as a pad of a bare chip (for example, an aluminum (Al) pad) or a bump structure formed on the pad.

The semiconductor chip 120 may include various types of integrated circuits formed on an active wafer including silicon (Si), germanium (Ge), or gallium arsenide (GaAs). The integrated circuit may be implemented as a processor chip such as a central processor (CPU), graphics processor (GPU), filled programmable gate array (FPGA), application processor (AP), digital signal processor, cryptographic processor, microprocessor, and microcontroller, but the invention is not limited thereto, and the integrated circuit may be implemented as a logic chip such as an analog-digital converter and an ASIC (application-specific IC), or a memory chip including a volatile memory (e.g., DRAM, SRAM), and/or a non-volatile memory (e.g., PRAM, MRAM, FeRAM, RRAM, flash memory).

The frame structure 130 may be disposed on the lower redistribution structure 110. The frame structure 130 may occupy a space surrounding the semiconductor chip 120 to improve stiffness and reduce warpage of the semiconductor package 100. Also, the frame structure 130 may provide an electrical path connecting the lower redistribution layer 112 to the upper redistribution layer 152 around the semiconductor chip 120. The frame structure 130 may include an insulating resin layer 131, an interconnection layer 132, and an interconnection via 133. Hereinafter, the frame structure 130 may be referred to as “interconnection structure.”

The insulating resin layer 131 may include an insulating resin impregnated in a fiber layer FB. The fiber layer FB may be embedded in the insulating resin layer 131. The insulating resin layer 131 may include an insulating resin such as a thermosetting resin such as an epoxy resin or a thermoplastic resin such as polyimide. The frame structure 130 may be formed from and/or include the same material impregnating the fiber layer FB, for example, prepreg. The insulating resin layer 131 may further include an inorganic filler dispersed in the insulating resin.

The fiber layer FB may include reinforcing fibers to stiffen the frame structure 130. For example, the fiber layer FB may include at least one of carbon fiber, and glass fiber, but the invention is not limited thereto. The fiber layer FB may include first fibers F1 and second fibers F2 arranged to intersect or overlap with each other. For example, the fiber layer FB may be woven with first fibers F1 arranged in a first direction D1 and second fibers F2 arranged in a second direction D2 intersecting with the first direction D1.

The interconnection layer 132 may include multiple interconnection layers 132 and an interconnection layer 132 may be disposed at one or more surfaces of the insulating resin layer 131 (e.g., a top surface and/or a bottom surface). The interconnection layer 132 may provide upper and lower electrical connection paths for a package along with the interconnection via 133, and may redistribute the connection pad 120P. The interconnection layer 132 may be formed of and/or include copper (Cu), aluminum (Al), silver (Ag), tin (Sn), gold (Au), nickel (Ni), lead (Pb), titanium (Ti), or alloys thereof. The interconnection layer 132 may include a ground pattern, a power pattern, and a signal pattern, depending on a design of the corresponding layer. Also, the interconnection layer 132 may be formed through a plating process such as a semi additive process (“SAP”) or a modified semi additive process (“MSAP”), and may include a seed layer and a conductor layer. A thickness of each of the interconnection layers 132 may be greater than a thickness of each of the lower redistribution layers 112.

The interconnection via 133 may electrically connect interconnection layers 132 disposed at different layers (e.g., different vertical levels), and accordingly, the interconnection via 133 may form an electrical path in the frame structure 130. For example, the interconnection via 133 may electrically connect interconnection layers 132 disposed on both surfaces (e.g., a top surface and a bottom surface) of the insulating resin layer 131 to each other. The interconnection via 133 may be formed of and/or include copper (Cu), aluminum (Al), silver (Ag), tin (Sn), gold (Au), nickel (Ni), lead (Pb), titanium (Ti), or alloys thereof. The interconnection via 133 may be a filled type via filled with a metal material, or may be a conformal type via in which a metal material is formed along a wall surface of the via hole.

In example embodiments, a burr may be prevented in the fiber layer FB during a sawing process by forming a recess portion RS in a corner portion of the frame structure 130 and defects due to burrs in the fiber layer FB may be reduced and yield may be improved.

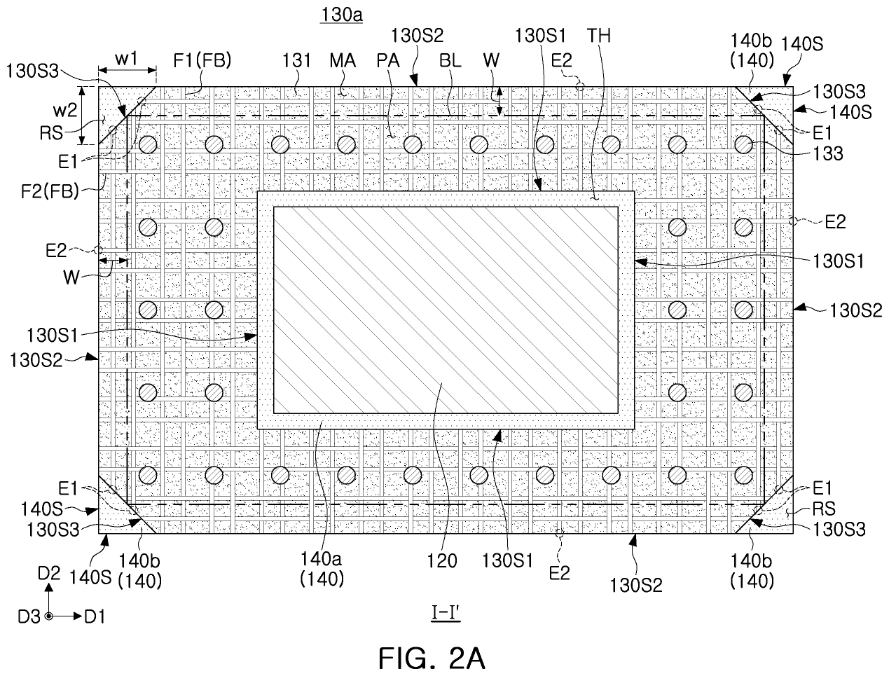

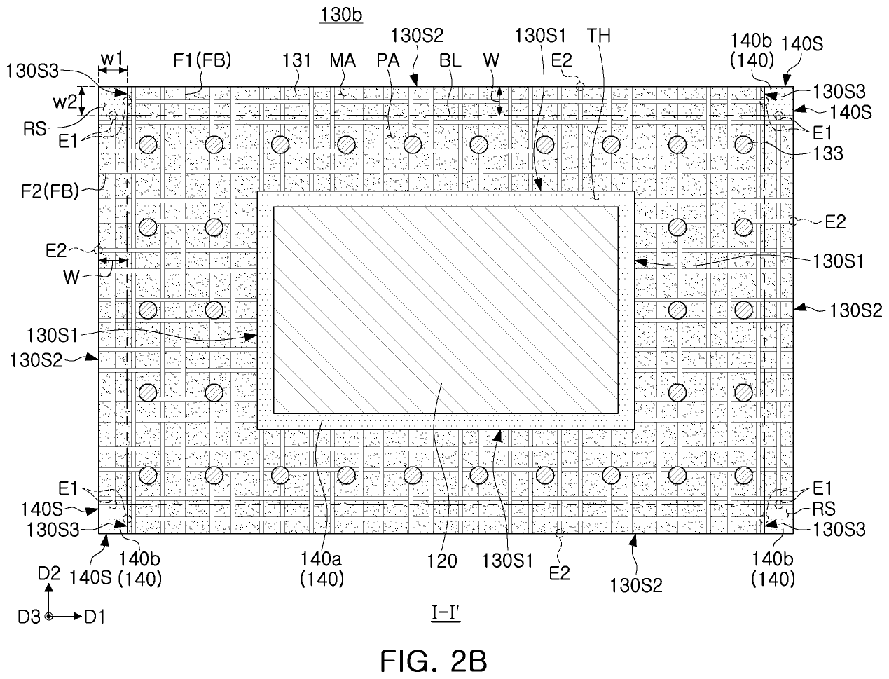

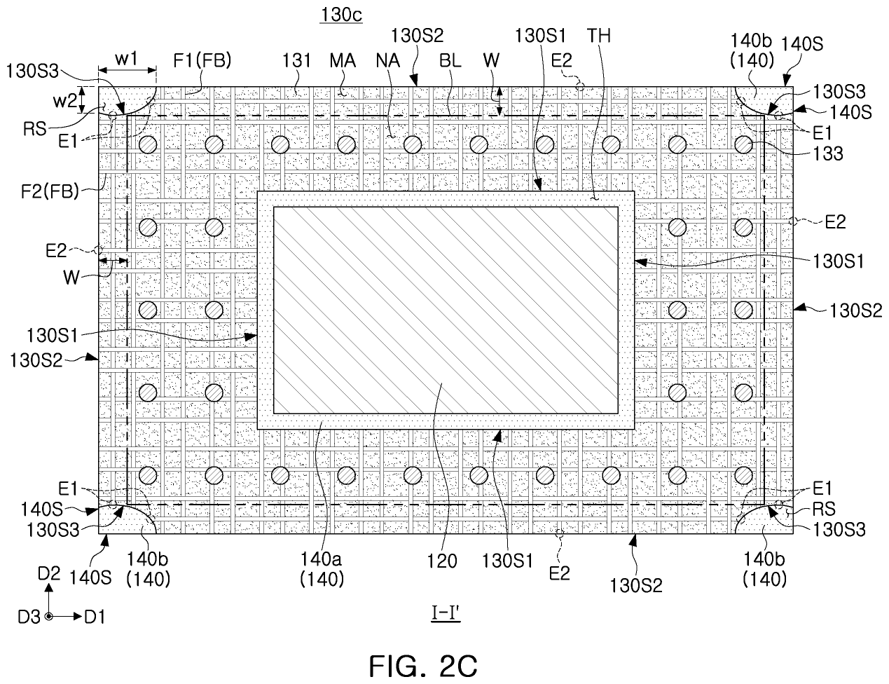

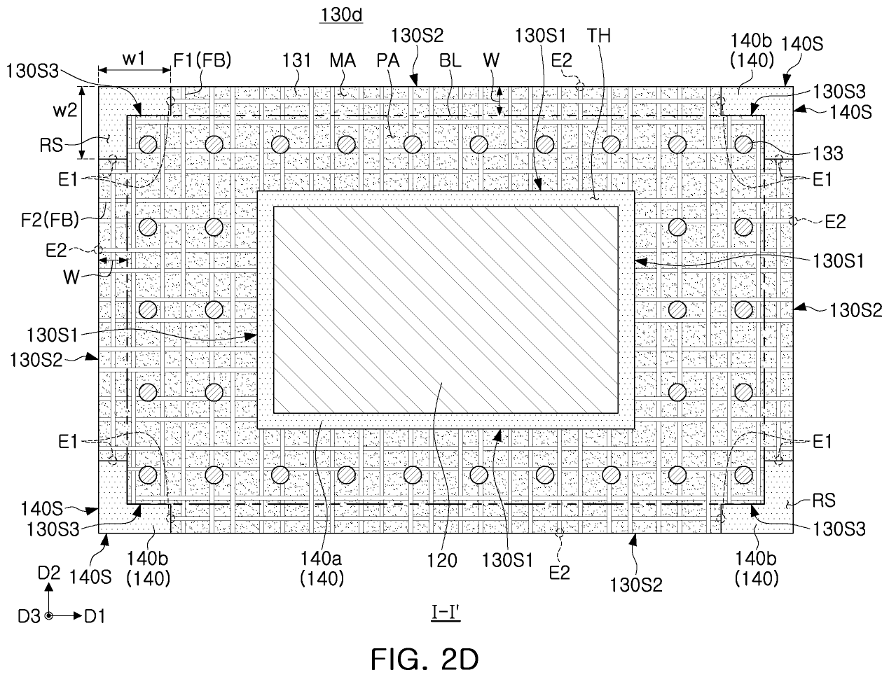

The frame structure 130 may have internal side surfaces 130S1 defining the through-portion TH, external side surfaces 130S2 opposite to the internal side surfaces 1301, and corner surfaces 130S3 defining the recess portions RS. The corner surfaces 130S3 may extend between external side surfaces 130S2 adjacent to each other. The through-portion TH may be a space in which the semiconductor chip 120 is accommodated, and the internal side surfaces 130S1 may surround and/or face side surfaces of the semiconductor chip 120. The external side surfaces 130S2 may include a side surface of the encapsulant 140 and a side surface of the frame structure 130. The corner surfaces 130S3 may connect ends of external side surfaces 130S2 that are adjacent to each other (e.g., the corner surfaces 130S3 may extend from one external side surface 130S2 to an adjacent external side surface 130S2. For example, the corner surfaces 130S3 may be curved surfaces connecting the ends of the external side surfaces 130S2 adjacent to each other. In example embodiments, the shape of the corner surfaces 130S3 may be varied (see FIGS. 2A to 2D).

The frame structure 130 may include a pattern region PA and a margin region MA. The pattern region PA may be understood as a region in which the interconnection layer 132 and the interconnection via 133 are formed. The margin region MA may be understood as a region in which the interconnection layer 132 and the interconnection via 133 are not formed. As illustrated in FIG. 1C, the pattern region PA may be a region around the through-portion TH, and the margin region MA may be an edge region of the frame structure 130. A boundary line BL between the pattern region PA and the margin region MA may be a conceptual line. The boundary line BL may be understood as a conceptual line to define a width of the margin region MA in terms of design.

The recess portions RS may be formed in the margin region MA of the frame structure 130. For example, on a plane such as a horizontal plane defined by a first direction D1 and a second direction D2, each of the recess portions RS may have a first horizontal width w1 in the first direction D1 and a second horizontal width w2 in the second direction D2, which may be equal to or greater than the width W of the margin region MA in the first direction D1 and/or the second direction D2. When the first horizontal width w1 and the second horizontal width w2 of the recess portions RS are smaller than the width W of the margin region MA, the effect of preventing burrs when cutting the fiber layer FB may be reduced. The width W of the margin region MA maybe in a range of about 100 μm to about 200 μm. In some examples, the width W of the margin region MA may be in the range of about 100 μm to about 180 μm, about 100 μm to about 170 μm, about 120 μm to about 170 μm, or about 130 μm to about 170 μm, but the invention is not limited thereto. The first horizontal width w1 and the second horizontal width w2 of the recess portions RS may be substantially the same as one another. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

The recess portions RS may be filled with an encapsulant 140. The encapsulant 140 in the recess portion RS, for example, a second portion 140b as described below, may have external surfaces 140S extending from the external side surfaces 130S2 adjacent to each other and joined by a corner surface 130S3. Each of the external surfaces 140S of the encapsulant 140 may be coplanar with the corresponding external side surfaces 130S2 adjacent to each other.

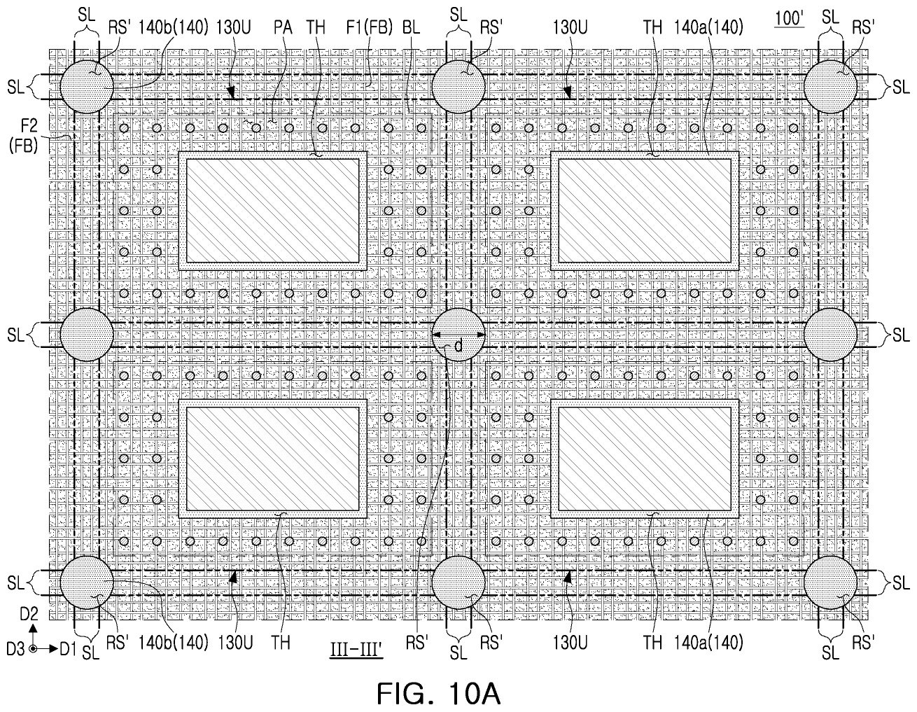

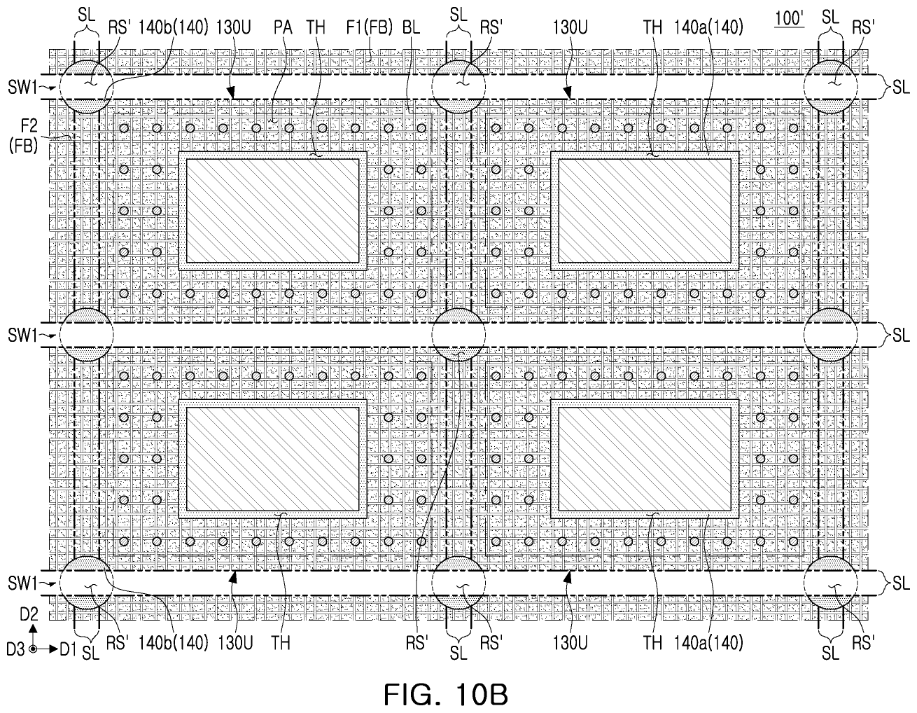

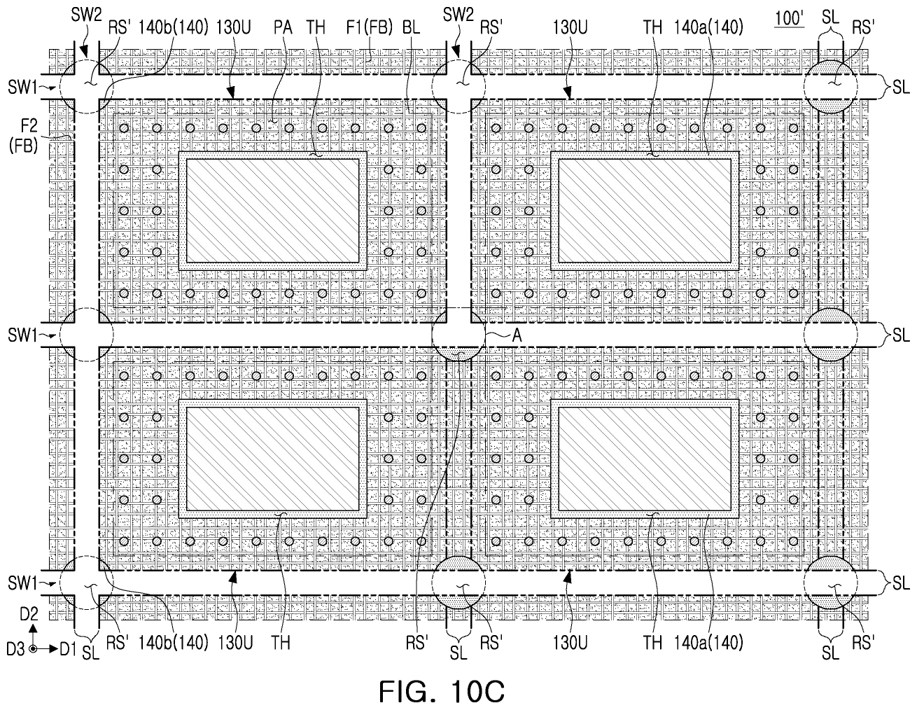

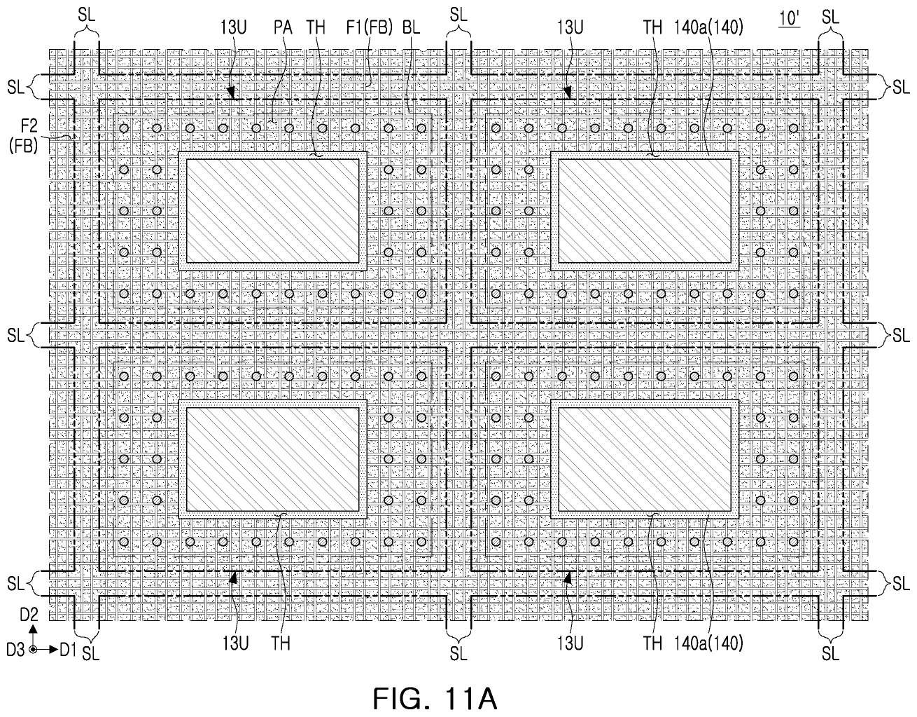

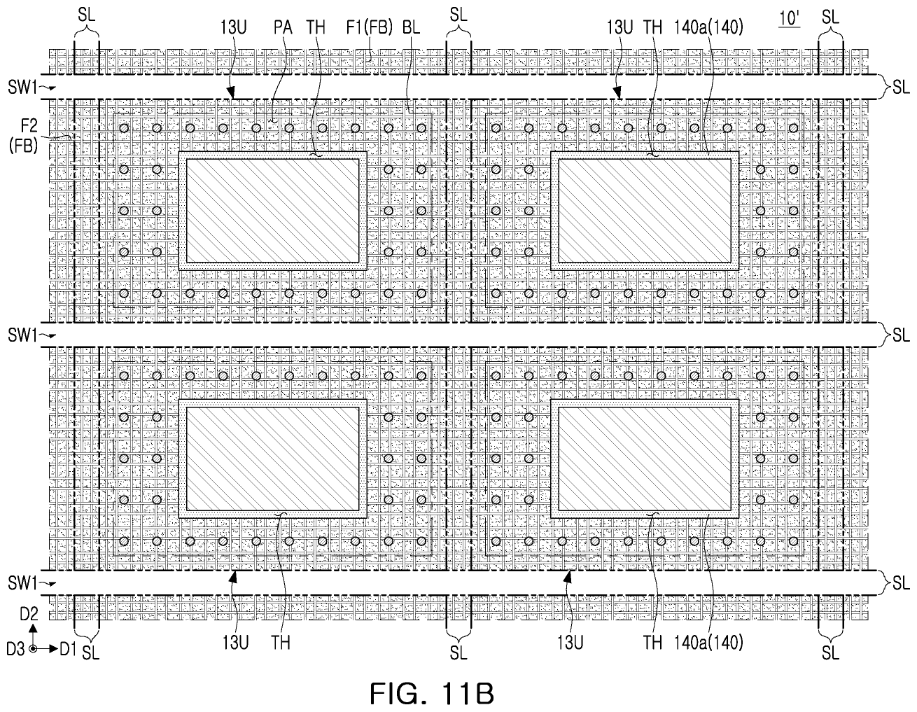

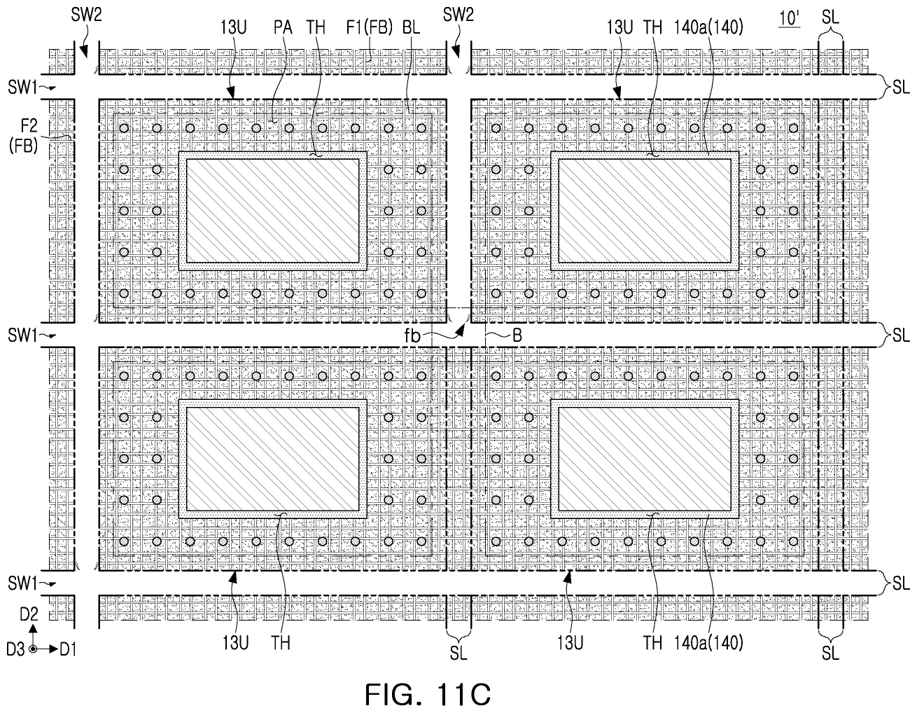

The fiber layer FB may be cut-out by the internal side surfaces 130S1, the external side surfaces 130S2, and the corner surfaces 130S3 (e.g., a lateral boundary of the fiber layer FB may be defined by the internal side surfaces 130S1, the external side surfaces 130S2, and the corner surfaces 130S3). The fiber layer FB may have at least a portion of fibers s cut-out by the corner surfaces 130S3 (e.g., an end of a fiber may extend to a corner surface 130S3). The fiber layer FB may have first fiber ends E1 adjacent to at least a portion of the corner surface 130S3 and second fiber ends E2 adjacent to at least a portion of the external side surface 130S2. The first fiber ends E1 of the fiber layer FB may be provided by at least a portion of the first fibers F1 and the second fibers F2. The first fiber ends E1 of the fiber layer FB may be spaced apart from the external surfaces 140S of the encapsulant 140. The first fiber ends E1 of the fiber layer FB may be in contact with (i.e., extend to) corresponding corner surfaces 130S3. The second fiber ends E2 of the fiber layer FB may be in contact with (i.e., extend to) corresponding external side surfaces 130S2. As the frame structure 130 in an example embodiment has the recess portion RS or the corner surfaces 130S3 cutting out (i.e., intersecting) the fiber layer FB on each corner as described above, during the sawing process burrs in the fiber layer FB that would otherwise be generated during the sawing process may be prevented and yield may be improved, which will be described in greater detail with reference to FIGS. 10A to 11C.

The encapsulant 140 may cover at least a portion of each of the semiconductor chip 120 and the frame structure 130. The encapsulant 140 may cover a side surface of the semiconductor chip 120, the internal side surfaces 130S1 of the frame structure 130, and the corner surfaces 130S3. The encapsulant 140 may be disposed in the through-portion TH and the recess portions RS of the frame structure 130. The encapsulant 140 may include a first portion 140a covering a side surface and an upper surface of the semiconductor chip 120, and a second portion 140b extending from the first portion 140a and covering an upper surface and the corner surfaces 130S3 of the frame structure 130. The encapsulant 140 may be formed of and/or include an insulating resin including an inorganic filler, for example, ABF, EMC, or the like. The first portion 140a and the second portion 140b of the encapsulant 140 may each include the same material as one another. The second portion 140b of the encapsulant 140 may have external surfaces 140S coplanar with the external side surfaces 130S2 of the frame structure 130.

The upper redistribution structure 150 may be disposed on the encapsulant 140 and may include an upper insulating layer 151, an upper redistribution layer 152, and an upper redistribution via 153 penetrating through the upper insulating layer 151 and electrically connecting the upper redistribution layer 152 to the interconnection layers 132. The upper insulating layer 151, the upper redistribution layer 152, and the upper redistribution via 153 may be configured the same as or similarly to the lower insulating layer 111, the lower redistribution layer 112, and the lower redistribution via 113 described above and redundant descriptions may be omitted hereafter.

The upper insulating layer 151 may be formed of and/or include a different type of insulating resin, different from that of the encapsulant 140. The upper insulating layer 151 may be formed of and/or include a material suitable for forming the upper redistribution layer 152 and the upper redistribution via 153 at a fine pitch, for example, a photosensitive resin such as PID.

In example embodiments, the upper redistribution layer 152 may include an intermediate pattern layer 152G disposed on the first portion 140a of the encapsulant 140. The intermediate pattern layer 152G may be electrically connected to the upper redistribution layer 152 in a region not illustrated in the diagram. The intermediate pattern layer 152G may be a ground pattern or a power pattern, but the invention is not limited thereto.

In example embodiments, the upper redistribution structure 150 may further include a surface finishing layer 152P and/or an upper protective layer 151PV. The surface finishing layer 152P may be disposed on the uppermost upper redistribution layer 152. The surface finishing layer 152P may be formed of and/or include nickel (Ni) and/or gold (Au). The upper protective layer 151PV may cover the uppermost upper redistribution layer 152. The upper protective layer 151PV may be formed of and/or include an insulating resin such as ABF. The upper protective layer 151PV may have openings exposing at least a portion of the surface finishing layer 152P.

FIGS. 2A to 2D are diagrams illustrating a frame structure of a modified example, illustrating various shapes of corner surfaces 130S3 applicable to example embodiments.

Referring to FIG. 2A, the frame structure 130a in the modified example may have internal side surfaces 130S1, external side surfaces 130S2, and corner surfaces 130S3 between the external side surfaces 130S2 adjacent to each other. In the modified example, corner surfaces 130S3 may be planes connecting ends of external side surfaces 130S2 adjacent to each other. For example, on a plane, the corner surfaces 130S3 may be illustrated as a linear line or a line segment connecting the ends of external side surfaces 130S2 adjacent to each other. The corner surfaces 130S3 may define a recess portion RS having a triangular shape. The recess portion RS may have a first horizontal width w1 and a second horizontal width w2 greater than the width W of the margin region MA, but the invention is not limited thereto.

Referring to FIG. 2B, the frame structure 130b in the modified example may have the corner surfaces 130S3 bent (i.e., at an angle) in the margin region MA. In a modified example, the corner surfaces 130S3 may be a bent surface connecting the ends of external side surfaces 130S2 adjacent to each other. For example, on a plane, the corner surfaces 130S3 may be illustrated as two linear lines or line segments connecting the ends of external side surfaces 130S2 adjacent to each other. The corner surfaces 130S3 may define a recess portion RS having a quadrangular shape. The recess portion RS may have a first horizontal width w1 and a second horizontal width w2 substantially equal to the width W of the margin region MA. In example embodiments, the recess portion RS may have a first horizontal width w1 or a second horizontal width w2 greater than the width W of the margin region MA.

Referring to FIG. 2C, the frame structure 130c in the modified example may include a recess portion RS having the first horizontal width w1 and the second horizontal width w2 which may be different from each other. In a modified example, the corner surfaces 130S3 may define a portion having an elliptic shape or a recess portion RS having a quadrangular shape. For example, on a plane, the corner surfaces 130S3 may be illustrated as a single curved line connecting the ends of external side surfaces 130S2 adjacent to each other. The first horizontal width w1 of the recess portion RS may be greater than the width W of the margin region MA. The second horizontal width w2 of the recess portion RS may be substantially equal to the width W of the margin region MA.

Referring to FIG. 2D, the frame structure 130d in the modified example may have the corner surfaces 130S3 bent in the margin region MA. In the modified example, the corner surfaces 130S3 may be illustrated as four linear lines or line segments connecting the ends of external side surfaces 130S2 adjacent to each other. The corner surfaces 130S3 may define a recess portion RS having a “L” shape. The recess portion RS may have a first horizontal width w1 and a second horizontal width w2 greater than the width W of the margin region MA.

As described above, the frame structure 130 applicable to embodiments may include various types of recess portion RS in a range in which the frame structure 130 does not overlap the pattern region PA.

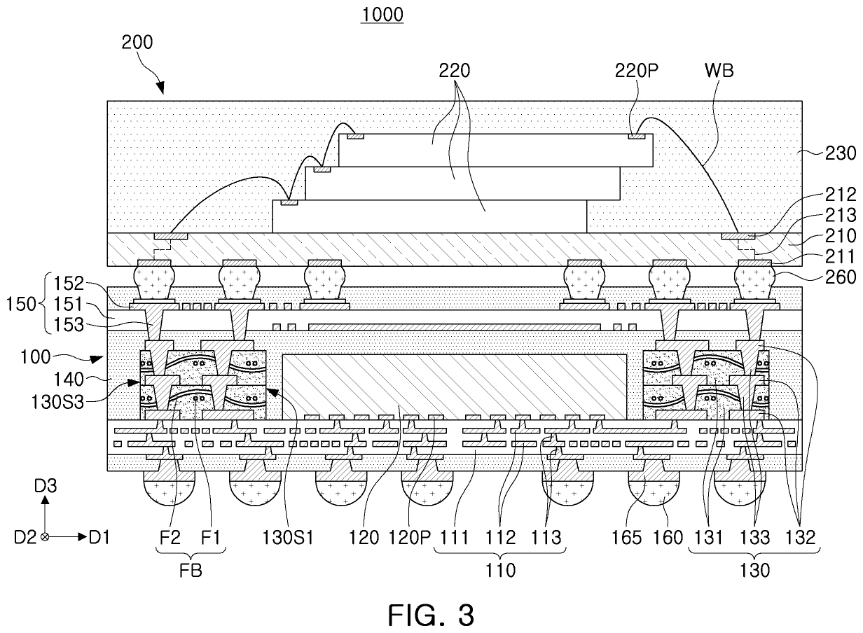

FIG. 3 is a cross-sectional diagram illustrating a semiconductor package according to an example embodiment.

Referring to FIG. 3, a semiconductor package 1000 in an example embodiment may have a package-on-package structure including a first package 100 and a second package 200. The first package 100 may be configured the same as or similarly to the semiconductor package 100 described with reference to FIGS. 1A to 2D.

The second package 200 may include a redistribution substrate 210, a second semiconductor chip 220, and a second encapsulant 230. The redistribution substrate 210 may include a lower pad 211 and an upper pad 212. The redistribution substrate 210 may include a redistribution circuit 213 connected to the lower pad 211 and the upper pad 212.

The second semiconductor chip 220 may be mounted on the redistribution substrate 210 using a wire bonding method or a flip chip bonding method. For example, the plurality of second semiconductor chips 220 may be stacked on the redistribution substrate 210 in a vertical direction and may be electrically connected to the upper pad 212 of the redistribution substrate 210 by bonding wire WB. In one example, the second semiconductor chip 220 may include a memory chip, and the first semiconductor chip 120 may include an AP chip.

The second encapsulant 230 may include material the same as or similar to the encapsulant 140 of the first package 100. The second package 200 may be physically and electrically connected to the first package 100 by the conductive bump 260. The conductive bump 260 may be electrically connected to the redistribution circuit 213 of the redistribution substrate 210 through the lower pad 211. The conductive bump 260 may be formed of and/or include a low melting point metal, for example, tin (Sn) or an alloy including tin (Sn).

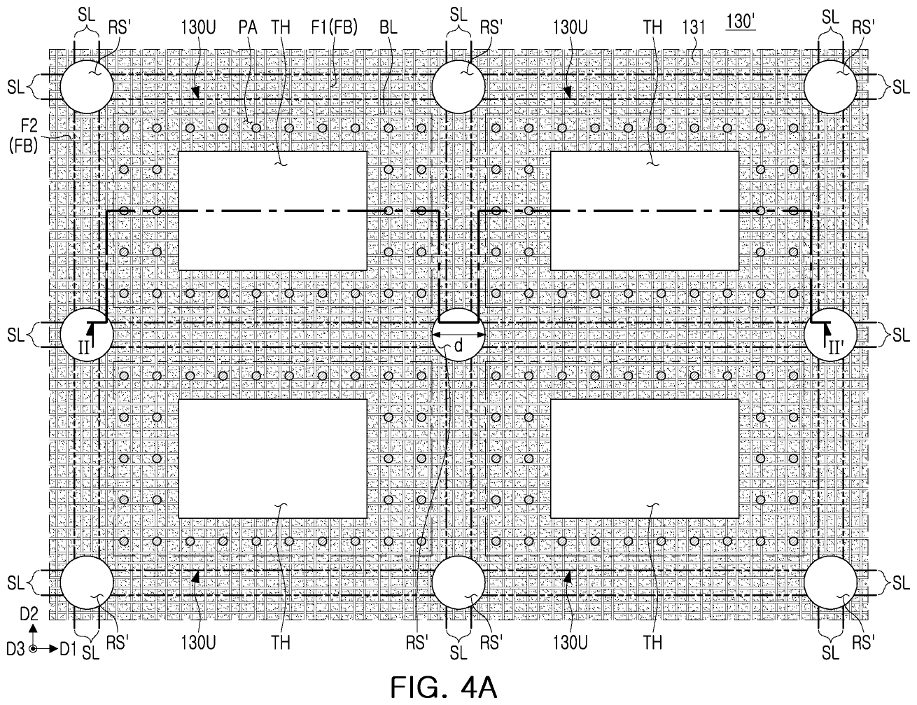

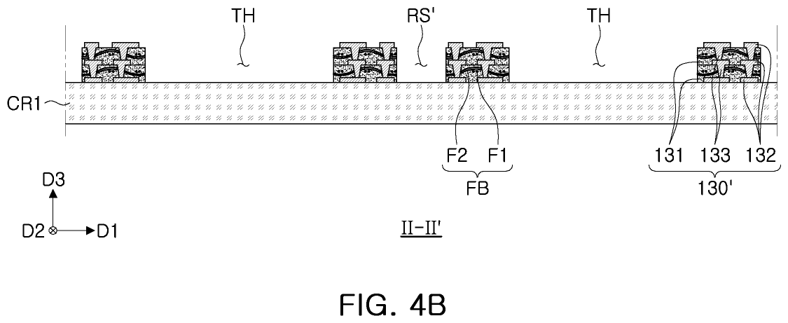

FIGS. 4A to 9 are diagrams illustrating a process of manufacturing a package structure according to an example embodiment.

FIG. 4B illustrates a cross-sectional surface taken along line II-II′ in FIG. 4A. Referring to FIGS. 4A and 4B, a substrate structure 130′ in which the plurality of first through-portions TH and the plurality of second through-portions RS′ are formed may be prepared.

The substrate structure 130′ may be attached to the first carrier CR1. The first carrier CR1 may include adhesive tape which may support and fix the substrate structure 130′ in subsequent processes. The substrate structure 130′ may include unit frames 130U divided by a scribe line SL (e.g., the substrate structure 130′ may be organized by unit frames 130U divided by scribe lines SL). Each of the unit frames 130U may include a fiber layer FB, an insulating resin layer 131, an interconnection layer 132, and an interconnection via 133 described with reference to FIG. 1C.

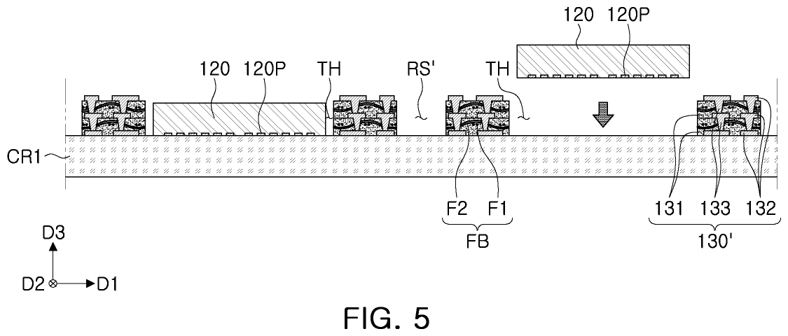

A plurality of first through-portions TH may be formed in the pattern region PA of the unit frames 130U. The plurality of second through-portions RS′ may be formed in a portion in which scribe lines SL intersect with each other. The plurality of first through-portions TH and the plurality of second through-portions RS′ may be formed by removing a portion of the fiber layer FB and the insulating resin layer 131. For example, the portion of fiber layer FB may be removed using a laser drill. The plurality of first through-portions TH may be formed to each have an area larger than the semiconductor chip (‘120’ in FIG. 5) to be attached later. The plurality of second through-portions RS′ may be formed to each have a width or a diameter greater than a distance between the unit frames 130U adjacent to each other. For example, a second through-portions RS′ may have a diameter d substantially equal to a distance between the pattern regions PA adjacent to each other.

After a sawing process, which will be described in greater detail later, a portion of each of the plurality of second through-portions RS′ may provide the corner surfaces 130S3 in FIG. 1C.

Referring to FIG. 5, semiconductor chips 120 may be attached to the first carrier CR1. The semiconductor chips 120 may be disposed in the plurality of first through-portions TH of the substrate structure 130′. The semiconductor chips 120 may be disposed to be faced-down such that the connection pads 120P may face downwardly.

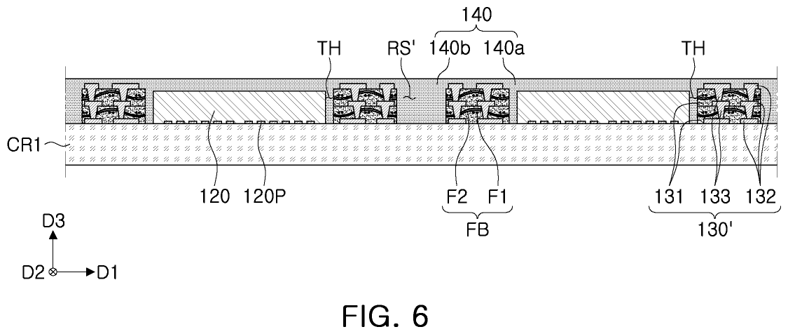

Referring to FIG. 6, an encapsulant 140 may be formed on the first carrier CR1. For example, the encapsulant 140 may be formed by transferring a film-type insulating resin such as ABF to the first carrier CR1. The encapsulant 140 may be filled in the plurality of first through-portions TH and the plurality of second through-portions RS′. The encapsulant 140 may include a first portion 140a disposed in the plurality of first through-portions TH and a second portion 140b disposed in the plurality of second through-portions RS′. The second portion 140b of the encapsulant 140 may cover the first fiber ends E1 of the fiber layer FB in the plurality of second through-portions RS′. A planarization process may be applied to an upper portion of the encapsulant 140.

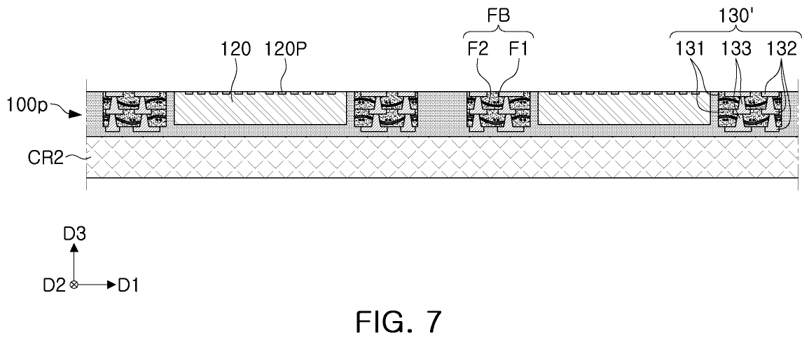

Referring to FIG. 7, the first carrier CR1 may be removed and the preliminary package structure 100p may be attached to a second carrier CR2. The preliminary package structure 100p may include a semiconductor chip 120, a substrate structure 130′, and an encapsulant 140. The preliminary package structure 100p may be attached to the second carrier CR2 such that the connection pad 120P of the semiconductor chip 120 may be exposed upwardly.

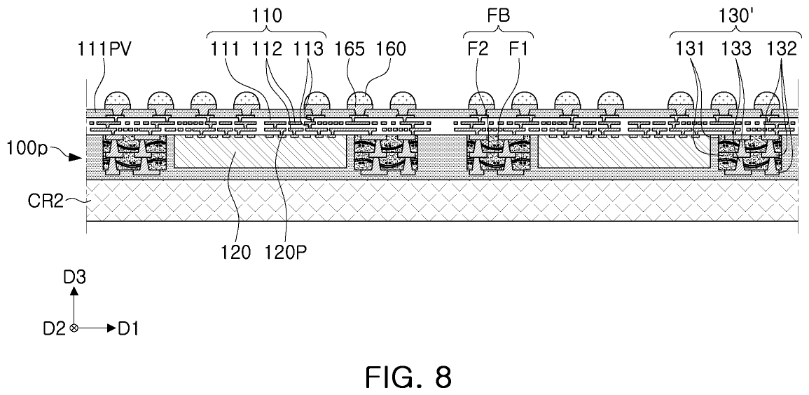

Referring to FIG. 8, a lower redistribution structure 110, a lower protective layer 111PV, an underbump layer 165, and connection bumps 160 may be formed on the preliminary package structure 100p.

The lower redistribution structure 110 may include a lower insulating layer 111, a lower redistribution layer 112, and a lower redistribution via 113. The lower insulating layer 111 may be formed by applying and curing a photosensitive material, for example, PID. Thereafter, via-holes penetrating through the lower insulating layer 111 may be formed by performing an exposure process and a development process using a photomask. Thereafter, a lower redistribution via 113 and a lower redistribution layer 112 may be formed using a deposition process, a plating process, and an etching process. By repeatedly performing the above-described process, a lower redistribution structure 110 including the plurality of lower insulating layers 111 and the plurality of lower redistribution layers 112 may be formed.

The lower protective layer 111PV may be formed using, for example, ABF. The underbump layer 165 may be formed using a plating process. The connection bumps 160 may be formed by attaching flux and solder balls to the underbump layer 165 and using a reflow process.

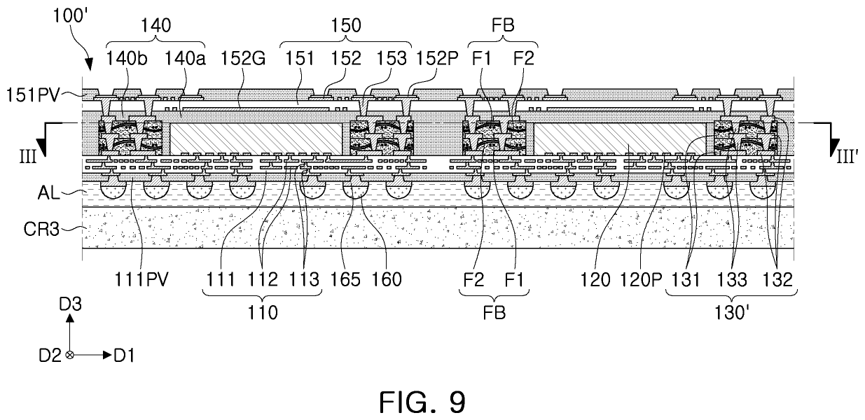

Referring to FIG. 9, a package structure 100′ may be manufactured by forming the upper redistribution structure 150, the upper protective layer 151PV, and the surface finishing layer 152P. The package structure 100′ may be attached to a third carrier CR3 such that the connection bumps 160 may be embedded in an adhesive layer AL.

The upper redistribution structure 150 may include an upper insulating layer 151, upper redistribution layers 152, and an upper redistribution vias 153. The upper insulating layer 151, the upper redistribution layers 152, and the upper redistribution via 153 may be formed in a similar manner to that of the lower insulating layer 111, the lower redistribution layer 112, and the lower redistribution via 113 described with reference to FIG. 8. Thereafter, the package structure 100′ may be separated into unit packages through a sawing process described later.

FIGS. 10A to 10C are diagrams illustrating a process of sawing a package structure according to an example embodiment. FIG. 10A illustrates a cross-sectional surface taken along line III-III′ in FIG. 9.

Referring to FIG. 10A, a portion of a fiber layer FB may be cut out. For example, a portion between adjacent scribe lines SL that extends between second through-portions RS′ may be cut out which may include, for example, a portion of each of first fibers F1 and second fibers F2. Before performing a sawing process, the plurality of second through-portions RS′ may be filled by an encapsulant 140. By removing the fiber layer FB disposed in an intersection portion of the scribe line SL in advance, burrs generated in an intersecting portion of the cutting line may be prevented.

Referring to FIG. 10B, a package structure 100′ may be cut-out along scribe lines SL extending in the first direction D1. The first cutting lines SW1 formed by a sawing process may penetrate through the second portion 140b of the plurality of second through-portions RS′ and the encapsulant 140.

Referring to FIG. 10C, the package structure 100′ may be cut-out along scribe lines SL extending in the second direction D2. The second cutting lines SW2 may intersect with the first cutting lines SW1 and may penetrate through the second portion 140b of the plurality of second through-portions RS′ and the encapsulant 140. In a portion A in which the second cutting lines SW2 and the first cutting lines SW1 intersect with each other, the second portion 140b of the encapsulant 140 may prevent the fiber layer FB from bending toward the first cutting lines SW1. Accordingly, burrs of the fiber layer FB and defects caused by burrs may be prevented.

FIGS. 11A to 11C are diagrams illustrating a sawing process of a package structure 10′ of a comparative example in which the plurality of second through portions are not included.

Referring to FIG. 11A, a package structure 10′ in the comparative example may be configured the same as or similar to the package structure 100′ described with reference to FIG. 10A, other than the plurality of second through-portions RS′ are not included. The package structure 10′ in the comparative example may include unit frames 13U divided by the scribe line SL.

Referring to FIG. 11B, the package structure 10′ in the comparative example may be cut-out along scribe lines SL extending in the first direction D1. Through a sawing process, first cutting lines SW1 horizontally passing through the package structure 10′ in the comparative example may be formed.

Referring to FIG. 11C, the package structure 10′ in the comparative example may be cut-out along scribe lines SL extending in the second direction D2. A second cutting line SW2 vertically passing through the package structure 10′ in the comparative example may be formed. In a portion B in which the second cutting lines SW2 and the first cutting lines SW1 intersect each other, a cutting portion fb of a fiber layer FB may be bent toward the first cutting lines SW1 and burrs may be generated. In other words, the cutting portion fb of the fiber layer FB in the portion “B” may be bent into a void space of the adjacent first cutting line SW1 and may not be completely removed.

According to the aforementioned example embodiments, by including the frame structure of which a corner portion is cut-out, a semiconductor package having improved yield may be provided.

While the example embodiments have been illustrated and described above, it will be configured as apparent to those skilled in the art that modifications and variations may be made without departing from the scope of the invention.

What is claimed is:

1. A semiconductor package, comprising:
a lower redistribution structure including a lower redistribution layer;
an interconnection structure disposed on the lower redistribution structure, the interconnection structure having internal side surfaces defining a through-portion, external side surfaces opposite to the internal side surfaces, and corner surfaces defining recess portions, wherein the corner surfaces are between adjacent external side surfaces, and the interconnection structure including a fiber layer having first fiber ends adjacent to at least a portion of the corner surfaces, an insulating resin layer in which the fiber layer is embedded, and an interconnection layer disposed on at least one surface of the insulating resin layer and electrically connected to the lower redistribution layer;
a semiconductor chip disposed in the through-portion of the interconnection structure and including connection pads electrically connected to the lower redistribution layer;
an encapsulant disposed in the through-portion and the recess portions of the interconnection structure;
an upper redistribution structure disposed on the encapsulant and including an upper redistribution layer electrically connected to the interconnection layer; and
connection bumps disposed below the lower redistribution structure and electrically connected to the lower redistribution layer.

2. The semiconductor package of claim 1,
wherein the interconnection structure has a pattern region around the through-portion in which the interconnection layer is disposed and a margin region around the pattern region, and
each of the recess portions has a first horizontal width in a first direction and a second horizontal width in a second direction equal to or greater than a width of the margin region on a horizontal plane.

3. The semiconductor package of claim 2, wherein the recess portions are disposed in the margin region.

4. The semiconductor package of claim 2, wherein the width of the margin region is in a range of 100 μm to 200 μm.

5. The semiconductor package of claim 2, wherein the first horizontal width and the second horizontal width of the recess portions are the same as one another.

6. The semiconductor package of claim 1,
wherein the encapsulant in a first recess portion of the recess portions has external surfaces extending from two external side surfaces of the interconnection structure, and
wherein the first fiber ends of the fiber layer are spaced apart from the external surfaces.

7. The semiconductor package of claim 6, wherein each of the external surfaces is coplanar with a corresponding external side surfaces of two adjacent external side surfaces.

8. The semiconductor package of claim 1, wherein the fiber layer has second fiber ends adjacent to at least a portion of the external side surfaces.

9. The semiconductor package of claim 1, wherein the fiber layer is woven with first fibers arranged in a first direction and second fibers arranged in a second direction intersecting the first direction.

10. The semiconductor package of claim 9, wherein the first fiber ends are provided by at least a portion of the first fibers and the second fibers.

11. The semiconductor package of claim 1, wherein the corner surfaces are curved surfaces connecting ends of adjacent external side surfaces.

12. The semiconductor package of claim 1, wherein the corner surfaces are planes connecting ends of adjacent external side surfaces.

13. The semiconductor package of claim 1, wherein the corner surfaces are bent surfaces connecting ends of adjacent external side.

14. A semiconductor package, comprising:
a lower redistribution structure including a lower redistribution layer;
a semiconductor chip disposed on the lower redistribution structure and including connection pads electrically connected to the lower redistribution layer;
an interconnection structure surrounding the semiconductor chip, the interconnection structure having external side surfaces and corner surfaces between adjacent external side surfaces, and the interconnection structure including an insulating resin layer with an insulating resin impregnated in a fiber layer, interconnection layers disposed on two surfaces of the insulating resin layer, and an interconnection via penetrating the insulating resin layer and electrically connecting the interconnection layers to each other;
an encapsulant covering at least a portion of each of the semiconductor chip and the interconnection structure; and
an upper redistribution structure including an insulating layer disposed on the encapsulant, an upper redistribution layer on the insulating layer, and an upper redistribution via penetrating the insulating layer and electrically connecting the upper redistribution layer to the interconnection layers,
wherein the fiber layer has fiber ends with at least a portion cut-out by the corner surfaces.

15. The semiconductor package of claim 14, wherein the encapsulant includes a first portion covering a side surface and an upper surface of the semiconductor chip, and a second portion extending from the first portion and covering an upper surface and the corner surfaces of the interconnection structure.

16. The semiconductor package of claim 15, wherein the first portion and the second portion of the encapsulant include the same material.

17. The semiconductor package of claim 14, wherein the fiber layer includes at least one of a carbon fiber and a glass fiber.

18. A semiconductor package, comprising:
a lower redistribution structure including a lower redistribution layer;
a semiconductor chip disposed on the lower redistribution structure and including connection pads electrically connected to the lower redistribution layer;
a frame structure disposed on the lower redistribution structure and having internal side surfaces surrounding a side surface of the semiconductor chip, external side surfaces opposite to the internal side surfaces, and corner surfaces connecting adjacent external side surfaces; and
an encapsulant covering the side surface of the semiconductor chip and the corner surfaces of the frame structure.

19. The semiconductor package of claim 18, wherein the frame structure includes a fiber layer having first fibers and second fibers arranged to intersect with each other, and an insulating resin layer in which the fiber layer is embedded.

20. The semiconductor package of claim 19, wherein at least a portion of the first and second fibers have at least one end adjacent to the corner surfaces.
